(19) United States
(12) Patent Application Publication
(10) Pub. No.: US 2007/0247901 A1
(43) Pub. Date: Oct. 25, 2007

(54) Mesoscopic Magnetic Body Having Circular Single Magnetic Domain Structure, its Production Method, and Magnetic Recording Device Using the Same

(76) Inventors: Hiroyuki Akinaga, Ibaraki (JP); Kanta Ono, Ibaraki (JP); Masaharu Oshima, Tokyo (JP); Toshiyuki Taniuchi, Tokyo (JP)

Correspondence Address: KLARQUIST SPARKMAN, LLP, 121 SW SALMON STREET, SUITE 1600, PORTLAND, OR, 97204, US

(21) Appl. No.: 10/559,483

(22) PCT Filed: Jun. 4, 2004
(86) PCT No.: PCT/JP04/08182

§ 371 Date: Mar. 5, 2007

(30) Foreign Application Priority Data
Jun. 5, 2003 (JP) 2003-160325

(51) Int. Cl. G11C 11/15; G11C 11/14; H01F 10/08; H01F 7/02

(52) U.S. Cl. 365/173; 29/604; 335/302; 365/171

(57) ABSTRACT

The present invention provides a mesoscopic magnetic body comprising a tabular ferromagnetic body whose planar shape has an axis of symmetry, but which is not symmetric in the direction perpendicular to the axis of symmetry, and wherein the magnetic body shows a circular single domain structure upon removal of the external parallel magnetic field. MRAMs which apply such a mesoscopic magnet and production methods thereof are also provided. As a result, it is possible to control the magnetization direction in nano-scale mesoscopic magnets as well as eliminate the limitation on the number of times in rewriting and writing.

### TECHNICAL FIELD

The present invention relates to a mesoscopic magnetic body having a static circular single domain structure, where the direction of its magnetization loop is controllable, a magnetic recording device comprising the mesoscopic magnet positioned on a substrate, their production method, and in particular, to a magnetic random access memory produced by using the magnetic recording device.

### BACKGROUND ART

The next generation of main memory is required to have a near-SRAM high speed, a near-DRAM integration scale, unlimited rewritability, and nonvolatility. MRAM is considered potent in view of such requirements.

MRAM stands for magnetic random access memory, which is a memory that combines magnetoresistive elements and standard semiconductor technology. Characteristic features of the MRAM include nonvolatility, low voltage operation, unlimited number of read/write operations, high read/write speed, and excellent radiation resistance.

A magnetoresistive element is an element that has a state of high resistance value or low resistance value depending on the state of magnetization. The magnetization state can be determined by measuring the resistance value. The resistance value can be measured, for example, by measuring tunneling current between the two ferromagnetic layers that sandwich a thin nonmagnetic layer (TMR: tunneling magneto-resistive).

Currently available MRAM will soon be put to practical use, at least, as an alternative to SRAM, since it has nonvolatile characteristics and can implement a cell area and access time equivalent to or less than SRAM. Use of MRAM is also expected in the field where flash EEPROM has been used.

Meanwhile, recording area in ultra-high density magnetic recording has reached nano-scale. A nano-scale magnetic body is known to exhibit a domain structure and a behavior such as magnetization reversal process, which are utterly different from the so-called bulk magnetism. For example, a micron or submicron sized magnetic disk is known to develop a vortex domain structure in the center region.

This is probably due to the energetically disadvantageous formation of domain wall in nano-scale magnets. The nano-scale magnetic body reduces magnetostatic energy by forming a concentric vortex structure in the center region to eliminate the domain wall. A nano-scale circular or ring-shaped ferromagnetic body has been reported to have a closed domain structure as well as a concentric vortex structure (See non-patent document 1).

However, the magnetization direction of such a nano-scale ferromagnetic disk may turn either clockwise or counterclockwise after the external magnetic field is removed, and could not be stably controlled (See non-patent documents 2 and 3).

With regard to a nano-scale ferromagnetic ring, the application and removal of an external magnetic field are known to cause transition in the whole ring from a single-direction magnetization state to a vortex structure through local formation and development of a vortex structure, and the transition can also occur in the reverse direction (See non-patent document 4).

There are two modes of transitional distortion of local magnetization: C mode and S mode, and C mode is known to be superior in for small sized magnets (See non-patent document 5).

[Non-Patent Document 1]

Journal of Japanese Society of Applied Physics, Vol. 26, No. 12 (2002) pp. 1168-1173

[Non-Patent Document 2]

Applied Physics Letters, Vol. 77, No. 18 (2000), pp. 2909-2911

[Non-Patent Document 3]

Physical Review Letters, Vol. 88, No. 15 (2002), pp. 157203-1-157203-4

[Non-Patent Document 4]

Journal Of Applied Physics, Vol. 92, No. 12 (2002), pp. 7397-7403

[Non-Patent Document 5]

Journal Of Applied Physics, Vol. 92, No. 3 (2002), pp. 1466-1472

An obstacle for broad applications of MRAM is the problem of cell area. In particular, when integrating MRAM with DRAM, an anticipated problem is that the same rule of design can not be applied to both RAMs since the cell area of MRAM is several times greater than that of DRAM.

For the currently available MRAMs, in the least, it is in principle difficult to reduce the write current due to the use of an induced field in writing MRAMs, and it is also difficult to reduce the wiring width and peripheral circuit area with an attempt to avoid effects from other induced fields. Accordingly, there is a strong demand for a device that can stably regulate magnetization with even a low write current.

When a nano-scale ferromagnetic body is adopted in an attempt to reduce cell area, its magnetization state is expected to have a vortex structure. In this case, the magnetization direction is extremely difficult to control, and it may be either clockwise or counterclockwise, depending on the distortion condition of the magnetization distribution generated in transitional phase.

Because of the uncontrollability of magnetization direction, for example, magnetoresistance cannot be employed for reading the magnetization state from the level of resistance value. As a consequence, when a nano-scale cell is adopted, the device cannot be used as a memory.

As described above, cell area nano-scaling is necessary for putting MRAM into practical use. However, the problem is that the magnetization state or magnetization chirality of such cells cannot be controlled by ordinary magnetization methods. Accordingly, while the currently available MRAMs may replace SRAM or flash EEPROM, they are not suitable for integration with DRAM and can hardly be used to replace DRAM.

An objective of the present invention is to solve the technical problems as described above, and to provide a magnetic memory device that can be integrated with DRAM or used as a DRAM-alternative main memory. The present invention includes the following technical subject matter.

### DISCLOSURE OF THE INVENTION

In order to achieve the objective described above, the present invention has adopted the following means for solving the problems.

### MEANS TO SOLVE THE PROBLEMS

[1] a mesoscopic magnetic body comprising a tabular ferromagnetic body, wherein planar shape of the magnetic body has an axis of symmetry but is asymmetric in the direction perpendicular to the axis of symmetry, wherein and the magnetic body shows a circular single domain structure upon removal of an external parallel magnetic field;

[2] a mesoscopic magnetic body comprising a ferromagnetic material, wherein the magnetic body has a planar portion that is parallel to an external parallel magnetic field which can be turned on/off and reversed, wherein

said planar portion is axially asymmetric in the direction of the external parallel magnetic field and has an axis of symmetry that is symmetric in the direction perpendicular to the external parallel magnetic field, and wherein

the magnetic body shows a circular single domain structure after removal of the applied external parallel magnetic field;

[3] the mesoscopic magnetic body according to [1] or [2], wherein

said planar portion has a shape formed by providing a notch to outer periphery of a shape that has two axes of symmetry perpendicular to each other, such that the notch is symmetric to one of the axes but not to the other axis, and wherein

upon application of the external parallel magnetic field, magnetic flux direction in periphery of the magnetic material shows a circumferential distribution which includes a part where change of the magnetic flux direction is discontinuous;

[4] the mesoscopic magnetic body according to [1] or [2], wherein

said planar portion has a shape corresponding to the contour of a projected image of a shape having two axes of symmetry perpendicular to each other over a rectangle that has one of the axes of symmetry as length and a length shorter than half of the other axis of symmetry as width, and wherein

upon application of the external parallel magnetic field, magnetization direction in the magnetic material's periphery shows a circumferential distribution, which includes a part where change of the magnetization direction is discontinuous;

[5] the mesoscopic magnetic body according to any one of [1] to [4] wherein said planar portion has a maximum width of 10 nm or less;

[6] a magnetic recording device comprising at least one ferromagnetic region layer on a non-ferromagnetic substrate, and an external magnetic field generating means that is capable of applying a parallel magnetic field, which can be turned on/off and reversed, to said ferromagnetic region layer, wherein

said ferromagnetic region layer has a planar shape that is asymmetric in the direction of the parallel magnetic field generated by said external magnetic field generating means, and which has an axis of symmetry that is symmetric in the direction perpendicular to the parallel magnetic field, and wherein

said ferromagnetic region layer takes a circular single domain structure after removal of the external magnetic field applied by said external magnetic field generating means, as well as a circular single domain structure with reverse magnetization direction after removal of applied reverse external magnetic field;

[7] a magnetic recording device comprising at least one ferromagnetic region layer on a non-ferromagnetic substrate, and an external magnetic field generating means that is capable of applying a parallel magnetic field, which can be turned on/off and reversed, to said ferromagnetic region layer, wherein

said ferromagnetic region layer has a planar shape that is asymmetric in the direction of the parallel magnetic field generated by said external magnetic field generating means, and which has an axis of symmetry that is symmetric in the direction perpendicular to the parallel magnetic field, and wherein

when direction of magnetic field applied by said external magnetic field generating means is not parallel to the axis of asymmetry of the ferromagnetic region layer, the circular single domain structure of the ferromagnetic region layer does not change after removal of the magnetic field;

[8] the magnetic recording device according to [6] or [7], wherein said ferromagnetic region layers sandwich a nonmagnetic layer to form a laminate in a vertical direction, and wherein either the upper or the lower ferromagnetic region layer is formed to have an aspect ratio larger than that of the other ferromagnetic region layers such that the magnetization directions of the ferromagnetic region layers with smaller aspect ratios can be controlled independently from the magnetization direction of the ferromagnetic region layer with a larger aspect ratio, and wherein the magnetization directions of the ferromagnetic region layers are detected based on resistance values between the ferromagnetic region layers;

[9] the magnetic recording device according to [8], wherein the differential aspect ratio is due to difference in thickness of the ferromagnetic region layers having an identical planar shape;

[10] the magnetic recording device according to [8], wherein the differential aspect ratio is due to difference in planar area of the ferromagnetic region layers;

[11] the magnetic recording device according to any one of [6] to [10], wherein

said planar portion has a shape formed by providing a notch to outer periphery of a shape having two axes of symmetry perpendicular to each other, such that the notch is symmetric to one of the axes but not to the other axis, and wherein

upon application of the external parallel magnetic field, magnetization direction in the ferromagnetic region layer's periphery shows a circumferential distribution, which includes a part where change of the magnetization direction is discontinuous;

[12] the magnetic recording device according to any one of [6] to [10], wherein

said planar portion has a shape corresponding to the contour of a projected image of a shape having two axes of symmetry perpendicular to each other over a rectangle that has one of the axes of symmetry as length and a length shorter than half of the other axis of symmetry as width, and wherein

upon application of the external parallel magnetic field, magnetization direction in the magnetic material's periphery shows a circumferential distribution, which includes a part where change of the magnetization direction is discontinuous;

[13] the magnetic recording device according to any one of [6] to [12], wherein said planar portion has a maximum width of 10 nm or less;

[14] the magnetic recording device according to any one of [6] to [14], further comprising a write bit line and a write word line wired above and below said ferromagnetic region layers, respectively, wherein axes of symmetry of said ferromagnetic region layers are positioned such that the composite magnetic field induced by electric currents applied to said lines functions as said external parallel magnetic field;

[15] the magnetic recording device according to any one of [6] to [14], wherein a plurality of ferromagnetic region layers are vertically positioned with nonmagnetic layers interpositioned between the ferromagnetic region layers such that the planar portions of the ferromagnetic region layers are parallel to one another, and wherein axes of symmetry of the planar portions are vertically positioned at a particular phase difference so that magnetization direction of any one or more of intermediate ferromagnetic region layers other than the lowermost and/or the uppermost ferromagnetic region layers can be independently controlled by the direction of the composite magnetic field induced from the write bit line and the write word line;

[16] a magnetic random access memory comprising a plurality of magnetic recording devices of [14] or [15] positioned on a non-ferromagnetic substrate such that each magnetic recording device can be selected independently;

[17] the magnetic random access memory according to [16], wherein said plurality of magnetic recording devices positioned on said non-ferromagnetic substrate are positioned such that the axes of symmetry of the planar portions of the ferromagnetic region layers of same height in adjacent magnetic recording devices are not in same direction;

[18] a method for producing a mesoscopic magnetic body having a circular single domain structure comprising at least the steps of:

placing a mesoscopic magnetic body which is a tabular ferromagnetic body whose planar portion has an axis of symmetry and is not symmetric in the direction perpendicular to the axis of symmetry, in a region within which an external parallel magnetic field can be applied, such that the axis of symmetry is perpendicular to the direction of the applied magnetic field, and

placing an external magnetic field generating means which is capable of applying the external parallel magnetic field to the mesoscopic magnetic body;

[19] the method for producing a mesoscopic magnetic body having a circular single domain structure according to [18], wherein said external magnetic field generating means is capable of turning the field on/off and reversing the field;

[20] the method for producing a mesoscopic magnetic body having a circular single domain structure according to [18] or [19], wherein the mesoscopic magnetic body has been patterned by any one of sputtering, electron beam evaporation, and molecular beam epitaxy, or a combination thereof;

[21] a method for producing a magnetic recording device comprising a mesoscopic magnetic body having a circular single domain structure, wherein the method comprises at least the steps of fabricating a write word line, fabricating a magnetoresistive element, and fabricating a write bit line on a nonmagnetic substrate; wherein

said step of providing a magnetoresistive element at least comprises the steps of:

placing a first mesoscopic magnetic body that is a tabular ferromagnetic body whose planar portion has an axis of symmetry and is not symmetric in the direction perpendicular to the axis of symmetry such that said axis of symmetry is perpendicular to the direction of the composite magnetic field induced by electric currents applied to said write word line and said write bit line;

depositing a nonmagnetic layer on said tabular ferromagnetic body to cover the upper surface of said ferromagnetic body; and

placing a second mesoscopic magnetic body that has the same material as said first mesoscopic magnetic body but a different aspect ratio, vertically above said first mesoscopic magnetic body on the nonmagnetic layer, such that boundaries between the layers are parallel to each other; and wherein

control of the induced composite magnetic field enables control of the magnetization direction of at least said mesoscopic magnetic body having a smaller aspect ratio, upon removal of the induced magnetic field;

[22] the method for producing a magnetic recording device according to [21], wherein the differential aspect ratio is due to difference in thickness of the ferromagnetic region layers having an identical planar shape;

[23] the method for producing a magnetic recording device according to [21], wherein the differential aspect ratio is due to difference in planar area of the ferromagnetic region layers;

[24] the method for producing a magnetic recording device according to any one of [18] to [23], wherein

said planar portion has a shape formed by providing a notch to outer periphery of a shape having two axes of symmetry perpendicular to each other such that the notch is symmetric to one of the axes but not to the other axis, and wherein

upon application of the external parallel magnetic field, magnetization direction in the ferromagnetic region layer's periphery shows a circumferential distribution, which includes a part where change of the magnetization direction is discontinuous;

[25] the method for producing a magnetic recording device according to any one of [18] to [23], wherein

said planar portion has a shape corresponding to the contour of a projected image of a shape having two axes of symmetry perpendicular to each other over a rectangle that has one of the axes of symmetry as length and a length shorter than half of the other axis of symmetry as width, and wherein

upon application of the external parallel magnetic field, magnetization direction in the magnetic material's periphery shows a circumferential distribution, which includes a part where change of the magnetization direction is discontinuous;

[26] the method for producing a magnetic recording device of any one of [18] to [25], wherein said planar portion has a maximum width of 10 nm or less;

[27] the magnetic recording device according to any one of [18] to [26], wherein a write bit line and a write word line are further provided above and below said ferromagnetic region layers, respectively, wherein axes of symmetry of said ferromagnetic region layers are positioned such that the composite magnetic field induced by electric current applied to said lines functions as said external parallel magnetic field;

[28] the method for producing a magnetic recording device according to any one of [18] to [27], wherein a plurality of ferromagnetic region layers are vertically positioned on one another with nonmagnetic layers interpositioned between the ferromagnetic region layers such that the planar portions of the ferromagnetic region layers are parallel to one another, and wherein axes of symmetry of the planar portions are vertically positioned at a particular phase difference so that magnetization direction of any one or more of intermediate ferromagnetic region layers other than the lowermost and/or the uppermost ferromagnetic region layers can be independently controlled by the direction of the composite magnetic field induced from the write bit line and the write word line;

[29] a method for producing a magnetic random access memory comprising the step of placing a plurality of magnetic recording devices on a non-ferromagnetic substrate using the method for producing a magnetic recording device of [27] or [28], such that each magnetic recording device can be selected independently; and

[30] the method for producing a magnetic random access memory according to [29], wherein

said plurality of magnetic recording devices positioned on said non-ferromagnetic substrate are positioned such that the axes of symmetry of the planar portions of the ferromagnetic region layers of same height in adjacent magnetic recording devices are not in the same direction.

The magnetization direction (the polarization direction) in a local region is not necessarily parallel to the external magnetic field even under the external magnetic field due to the effect of the geometrical anisotropy of the ferromagnetic body region, and discontinuity in the distribution of the magnetization direction is induced along the outer periphery of the ferromagnetic body region. This discontinuity in the distribution of the magnetization direction triggers local formation of the C mode vortex structure upon removal of the external magnetic field, and this vortex structure spreads over the entire ferromagnetic body region to form the circular single domain structure with vortex structure.

### BRIEF DESCRIPTION OF THE DRAWINGS

FIG. 1 is an illustrative diagram of the planar shape of the mesoscopic magnetic body of the present invention.

FIG. 2 shows the magnetization history against an external magnetic field in the mesoscopic magnetic body of the present invention.

FIG. 3 is an illustrative diagram of the magnetic recording system of the mesoscopic magnetic body of the present invention.

FIG. 4 shows the dependency of a vortex annihilation field on the thickness of magnetic body.

FIG. 5 shows the dependency of a vortex annihilation field on the diameter of magnetic body.

FIG. 6 is a cross sectional view of the device when an MRAM is constructed by using the mesoscopic magnetic body of the present invention.

FIG. 7 shows an embodiment of the cell arrangement when an MRAM is constructed by using the mesoscopic magnetic body of the present invention.

FIG. 8 shows the structure of a multilevel recording device of the present invention.

### BEST MODE FOR CARRYING OUT THE INVENTION

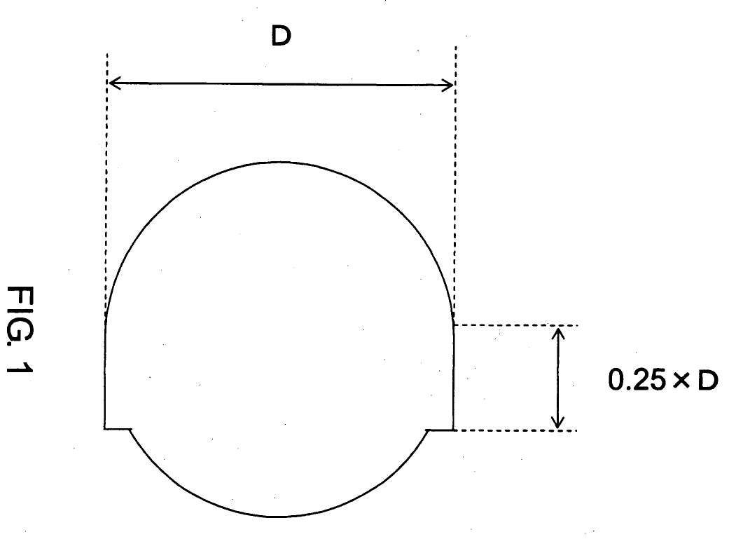

FIG. 1 shows an exemplary planar shape of the ferromagnetic body employed in the present invention. Basically, this planar shape is created by making a notch on or extending part of a circle, and is asymmetric in the direction of the external magnetic field but symmetric along its perpendicular direction.

The planar shape in FIG. 1 adopts a shape that corresponds to the projected image of a circle having a diameter (D) of 1 μm, wherein the circle is overlapped with a rectangle that has a length of D and a width of 0.25×D, such that one long side of the rectangle passes the center of the circle. The thickness of the plate is 50 nm. The shape used in the present invention is not limited to the one shown in FIG. 1.

### EXAMPLE 1

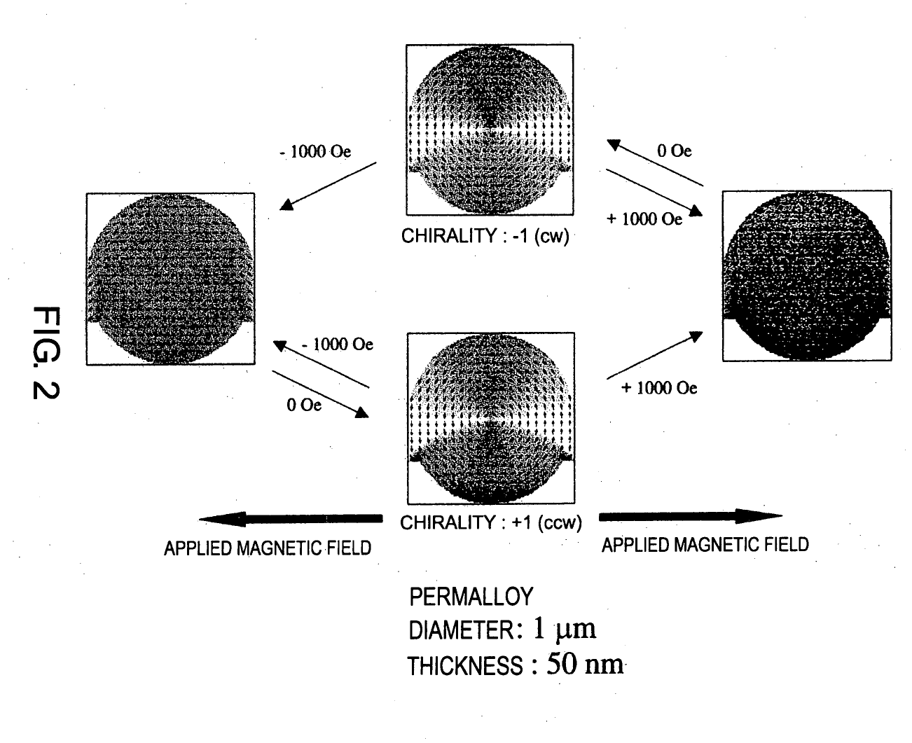

FIG. 2 shows the simulated magnetization direction when an external magnetic field of 1000 Oe is applied to the ferromagnetic body of FIG. 1. In this example, the long side of the rectangle is positioned in parallel to the applied direction of the external magnetic field, such that the ferromagnetic body is asymmetric with respect to the direction of the external magnetic field but symmetric with respect to the direction perpendicular to the external magnetic field.

The magnetization state when an external magnetic field of 1000 Oe is applied from left to right in the figure is shown in the square on the right-hand side of the figure. As a result of the external magnetic field penetrating through the ferromagnetic body, the magnetization direction in the ferromagnetic body became substantially parallel to the external magnetic field. It was then revealed that the magnetization direction in the rectangle portion projected from the periphery of the circle did not become completely parallel to the external magnetic field, and therefore cause discontinuity in the change of magnetization direction at the outer periphery of the ferromagnetic body. This is believed to be caused by the edge effect.

Next, the magnetization state after removal of the external magnetic field is shown in the square at the top of the figure. As a result of the removal, a closed single domain having a clockwise vortex structure was formed.

In addition, the magnetization state when an external magnetic field of 1000 Oe is applied in the opposite direction to a sample having such a vortex structure is shown in the square on the left-hand side of the figure. It was observed that the arrows (direction of magnetization) are mostly directed leftward in parallel with the external magnetic field.

When the external magnetic field is removed (reduced to 0 Oe) from the state with a leftward magnetization direction, a counterclockwise magnetization was observed as shown in the square at the bottom of the figure.

Moreover, applying a rightward or leftward external magnetic field to the counterclockwise magnetized magnetic body magnetizes the magnetic body to the same direction as the external magnetic field, demonstrating the reproducibility of the operation. Similarly, the magnetization direction could also be aligned in either direction as desired from the state shown at the top of the figure, depending on the direction of the external magnetic field applied.

These results confirmed that the direction at which magnetization is distributed, in particular, the chirality of the vortex structure in the ferromagnetic body region, can be freely controlled by switching the direction of the external magnetic field. It was also found that this control of magnetization direction is reversible and infinitely repeatable.

By comparing the Examples, it was revealed that a vortex is formed along the magnetization direction at the above-described sites where the change of direction is discontinuous. The discontinuity of magnetization direction is caused by the edge effect associated with geometric anisotropy against the external magnetic field. Magnetization components that are not formed symmetrically with respect to the direction of an external magnetic field may remain after removal of the external magnetic field, and such local distortion of magnetization becomes the trigger and extends to the entire magnetic body, and thereby decides the vortex chirality.

### EXAMPLE 2

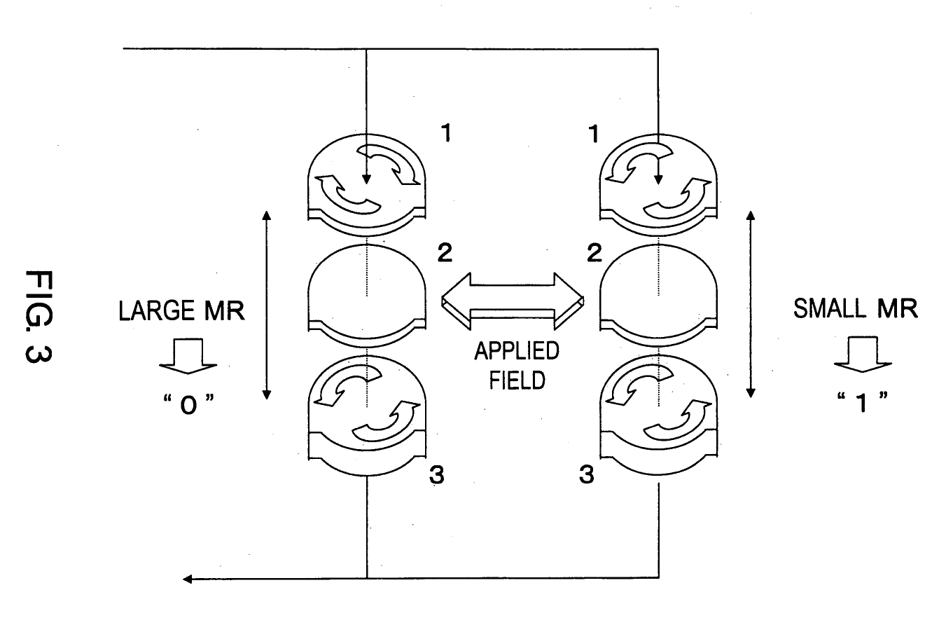

FIG. 3 is a diagram explaining the principle for construction of a magnetic recording device using the mesoscopic magnetic body of the present invention. In this example, a thin nonmagnetic layer (2) was sandwiched between the upper layer and the lower layer of the magnetic body of the present invention, and several of this were positioned in a plane. The lower magnetic body with increased layer thickness serves as the fixed layer (3) and the thin upper magnetic layer serves as the free layer (1).

When two ferromagnetic bodies are magnetized in the same direction, the resistance value between the two ferromagnetic layers is low, and when they are magnetized in opposite directions, the resistance value is high. This is known as the magnetoresistance effect. Thus, the device of the present invention is a magnetic recording device which writes by controlling the direction of vortex magnetic field in the free layer by means of an external magnetic field, and reads the information based on the direction determined by utilizing the magnetoresistance effect.

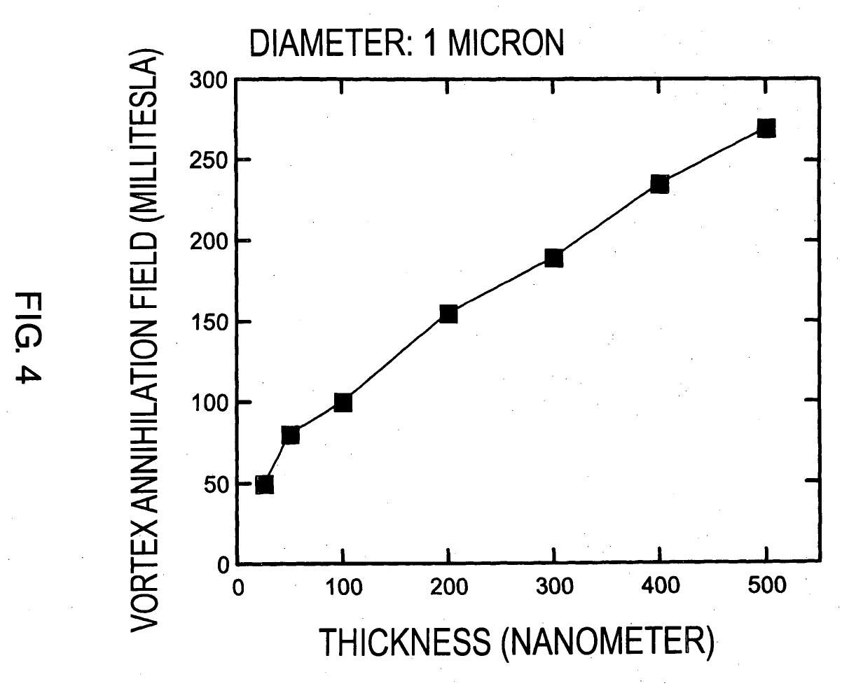

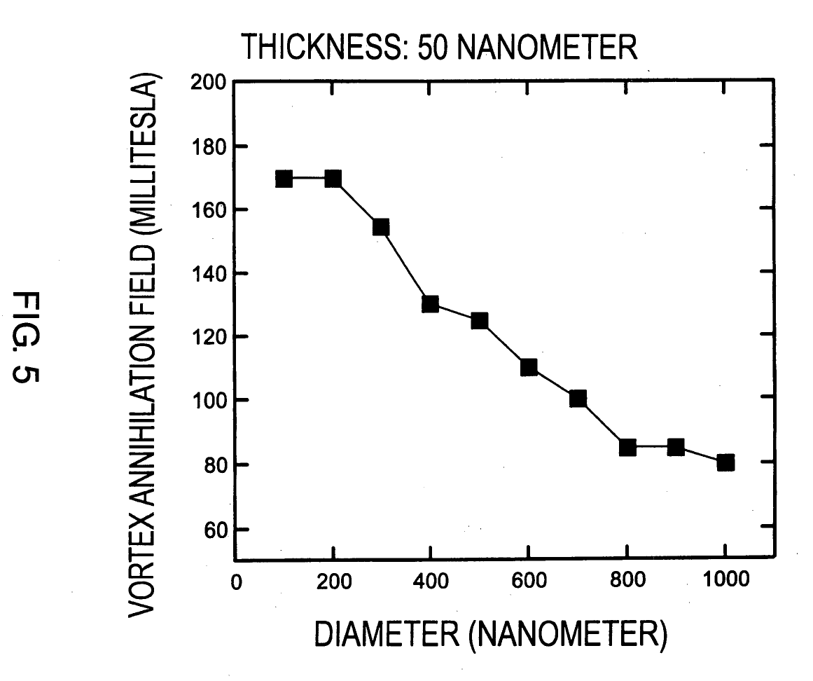

The geometry dependency of vortex magnetic field was measured, and the results are shown in FIGS. 4 and 5. FIG. 4 shows the result of measuring the external magnetic field intensity that the vortex magnetic field annihilates when ferromagnetic bodies of 1 μm diameter with various thicknesses are used. FIG. 5 shows the result of measuring the external magnetic field intensity that the vortex magnetic field annihilates when 50 nm-thick ferromagnetic bodies with various diameters are used.

These results indicate that the annihilation field for a vortex magnetic field can be differed by using shapes of different aspect ratios for the two ferromagnetic bodies that sandwich a nonmagnetic layer. Therefore, the ferromagnetic body having a shape with larger aspect ratio may be used as the fixed layer where magnetization direction is fixed, and the other ferromagnetic body may be used as the free layer whose magnetization direction is to be controlled by applying a magnetic field between the vortex annihilation field intensities of the two ferromagnetic bodies. This eliminates the need for a pinned layer in the present invention to fix the magnetization direction of one of the ferromagnetic bodies

### EXAMPLE 3

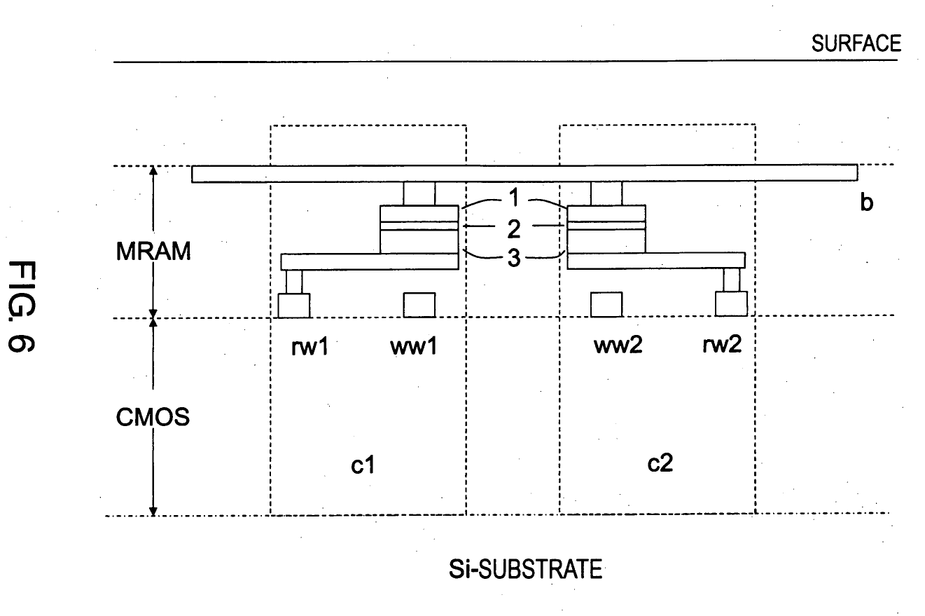

A magnetic random access memory was constructed by arranging the mesoscopic magnetic body of the present invention, such that the direction perpendicular to the magnetic body's axis of symmetry would be parallel to the direction of the composite magnetic field generated by the write bit line and the write word line (ww1, ww2). The cross-sectional view of the device is shown in FIG. 6. A read bit line and a read word line (rw1, rw2) were also provided separately. These read lines have a smaller amount of electric current than the write lines, and thus do not affect the magnetization direction in the magnetoresistive element.

Composition of induction fields does not take place at cells other than the cell at which the write bit line and the write word line (ww1, ww2) are crossed, and therefore, the amount of electric current for the write word line and the write bit line is set such that the induction fields of the write word line and the write bit line do not exceed the vortex annihilation field of the free layer.

When the upper and the lower ferromagnetic layers of the magnetoresistive element have the same magnetization direction, the resistance value between the upper and the lower ferromagnetic layers is low. When the magnetization directions are opposite to each other, the resistance value is high. Thus, the magnetization direction of free layer (1) of any desired cell can be read by selecting a desired cell and detecting the level of tunnel current from the read bit line and the read word line.

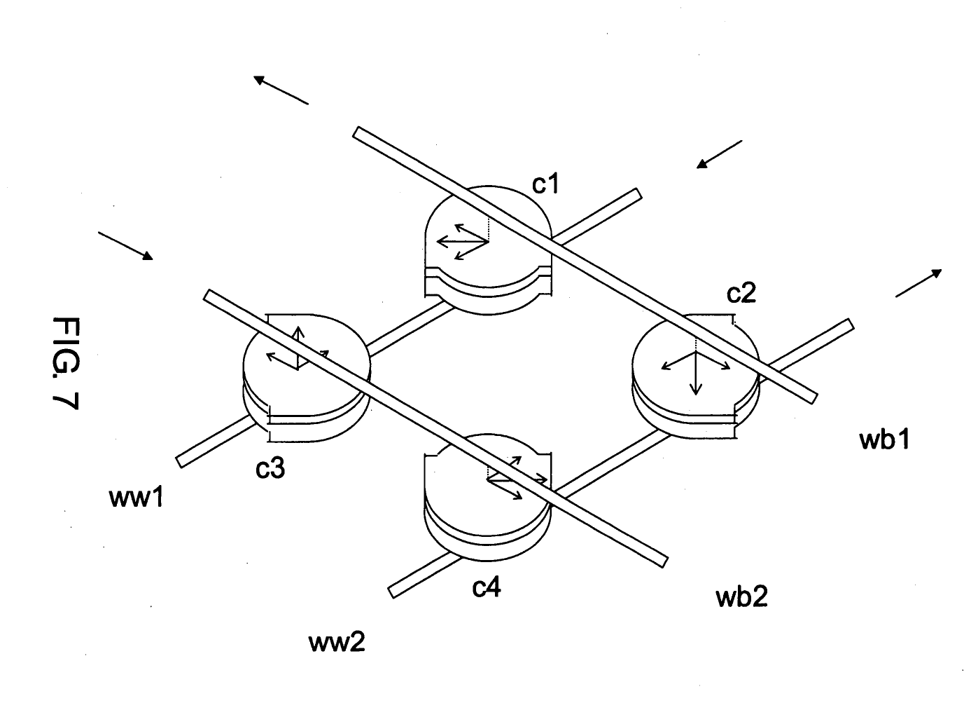

As shown in FIG. 7, when the cells are positioned such that the axes of symmetry of the adjacent cells are different from one another in direction, one cell is less affected by the induction field of the adjacent cells. Accordingly, such arrangement alleviates the cell separation problem, enabling further densification of cell arrangement.

### EXAMPLE 4

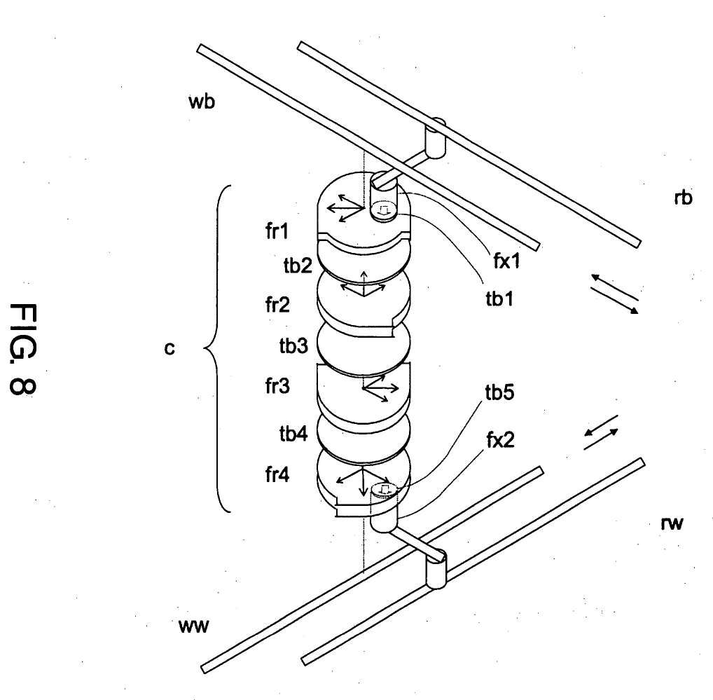

FIG. 8 is a schematic view of a cell constructed to record multiple values in one cell. Basically, a plurality of ferromagnetic body regions are layered in a vertical direction. First, the fixed layers (fx1, fx2) were configured to have a planar shape different from those of the free layers (fr1 to fr4). This enables the fixed layers to have a larger aspect ratio, and the magnetoresistance to be minimally affected by the disturbance of magnetization direction in the periphery of the free layers due to geometrical anisotropy.

The free layers (fr1 to fr4) were vertically positioned such that the axis of symmetry of the planar portion of each free layer differs by 90 degrees in phase, and tunnel barrier layers (tb1 to tb5) were inserted between the free layers. While the phase difference between adjacent free layers is not limited to 90 degrees, 90-degree phase difference facilitates the piling up of layers when considering the layout of write word lines and write bit lines.

In addition, only the magnetization direction of a desired free layer can be controlled by applying electric currents to write word lines and write bit lines, at a level such that the magnetic field in the direction perpendicular to the axis of symmetry of the desired free layer is greater than the vortex annihilation field of the free layer, and the magnetic field components in the direction perpendicular to the axis of symmetry of other free layers are weaker than the vortex annihilation field of the respective layer and the vortex annihilation field of the fixed layers.

However, the amount of information recorded is not two to the fourth power (the number of free layers=4) in this Example since the reading is carried out by detecting the resistance value between the fixed layers (rb1, rb2). At the same time, one cell can record three intensity values, and the values are 0, 2, and 4, while one free layer can record only two values: 0 and 1. Thus, a higher S/N ratio can be obtained and a sufficiently large change in resistance value is expected even with a reduced-sized cell.

### EFFECTS OF THE INVENTION

The present invention enables magnetization direction of a vortex structure to be controlled even in nano-scale mesoscopic magnets. As a result of this, further reduction in cell area becomes possible, which makes the technical prospective of DRAM integration and replacement of DRAM more likely.

Furthermore, since the magnetic body used in the present invention is geometrically anisotropic, if the magnetoresistive elements can be positioned in a vertical direction with their geometrically anisotropic axes of symmetry differed in phase, the effects of induction fields applied by the write word lines from other layers can be minimized, and multi-layered structures become possible and higher integration is expected. The present invention eliminates the use of a pinned layer for fixing the magnetization direction of one of the two magnets. Thus, production processes of devices such as MRAM can be simplified, and the relative production cost for integration density can be reduced.

1. A mesoscopic magnetic body comprising a tabular ferromagnetic body, wherein a planar portion of the magnetic body has an axis of symmetry but is asymmetric in the direction perpendicular to the axis of symmetry, and wherein the magnetic body shows a circular single domain structure upon removal of an external parallel magnetic field.

2. A mesoscopic magnetic body comprising a ferromagnetic material, wherein the magnetic body has a planar portion that is parallel to an external parallel magnetic field which can be turned on/off and reversed,
wherein said planar portion is axially asymmetric in the direction of the external parallel magnetic field and has an axis of symmetry that is symmetric in the direction perpendicular to the external parallel magnetic field, and
wherein the magnetic body shows a circular single domain structure after removal of the applied external parallel magnetic field.

3. The mesoscopic magnetic body according to claim 1, wherein said planar portion has a shape formed by providing a notch to the outer periphery of a shape that has two axes of symmetry perpendicular to each other, such that the notch is symmetric to one of the axes but not to the other axis, and
wherein upon application of the external parallel magnetic field, a magnetic flux direction in the periphery of the magnetic material shows a circumferential distribution which includes a part where change of the magnetic flux direction is discontinuous.

4. The mesoscopic magnetic body according to claim 1, wherein said planar portion has a shape corresponding to the contour of a projected image of a shape having two axes of symmetry perpendicular to each other over a rectangle that has one of the axes of symmetry as length and a length shorter than half of the other axis of symmetry as width, and
wherein upon application of the external parallel magnetic field, magnetization direction in the magnetic material's periphery shows a circumferential distribution, which includes a part where change of the magnetization direction is discontinuous.

5. The mesoscopic magnetic body according to claim 1 wherein said planar portion has a maximum width of 10 nm or less.

6. A magnetic recording device comprising at least one ferromagnetic region layer on a non-ferromagnetic substrate, and an external magnetic field generating means that is capable of applying a parallel magnetic field, which can be turned on/off and reversed, to said ferromagnetic region layer,
wherein said ferromagnetic region layer has a planar shape that is asymmetric in the direction of the parallel magnetic field generated by said external magnetic field generating means, and which has an axis of symmetry that is symmetric in the direction perpendicular to the parallel magnetic field, and
wherein said ferromagnetic region layer takes a circular single domain structure after removal of the external magnetic field applied by said external magnetic field generating means, as well as a circular single domain structure with reverse magnetization direction after removal of an applied reverse external magnetic field.

7. A magnetic recording device comprising at least one ferromagnetic region layer on a non-ferromagnetic substrate, and an external magnetic field generating means that is capable of applying a parallel magnetic field, which can be turned on/off and reversed, to said ferromagnetic region layer,
wherein said ferromagnetic region layer has a planar shape that is asymmetric in the direction of the parallel magnetic field generated by said external magnetic field generating means, and which has an axis of symmetry that is symmetric in the direction perpendicular to the parallel magnetic field, and
wherein when direction of magnetic field applied by said external magnetic field generating means is not parallel to the axis of asymmetry of the ferromagnetic region layer, the circular single domain structure of the ferromagnetic region layer does not change after removal of the magnetic field.

8. The magnetic recording device according to claim 6, wherein said ferromagnetic region layers sandwich a nonmagnetic layer to form a laminate in a vertical direction, and wherein either the upper or the lower ferromagnetic region layer is formed to have an aspect ratio larger than that of the other ferromagnetic region layers such that the magnetization directions of the ferromagnetic region layers with smaller aspect ratios can be controlled independently from the magnetization direction of the ferromagnetic region layer with a larger aspect ratio, and wherein the magnetization directions of the ferromagnetic region layers are detected based on resistance values between the ferromagnetic region layers.

9. The magnetic recording device according to claim 8, wherein the differential aspect ratio is due to a difference in thickness of the ferromagnetic region layers having an identical planar shape.

10. The magnetic recording device according to claim 8, wherein the differential aspect ratio is due to a difference in planar area of the ferromagnetic region layers.

11. The magnetic recording device according to claim 6, wherein said planar portion has a shape formed by providing a notch to the outer periphery of a shape having two axes of symmetry perpendicular to each other, such that the notch is symmetric to one of the axes but not to the other axis, and
wherein upon application of the external parallel magnetic field, magnetization direction in the ferromagnetic region layer's periphery shows a circumferential distribution, which includes a part where change of the magnetization direction is discontinuous.

12. The magnetic recording device according to claim 6, wherein said planar portion has a shape corresponding to the contour of a projected image of a shape having two axes of symmetry perpendicular to each other over a rectangle that has one of the axes of symmetry as length and a length shorter than half of the other axis of symmetry as width, and
wherein upon application of the external parallel magnetic field, magnetization direction in the magnetic material's periphery shows a circumferential distribution, which includes a part where change of the magnetization direction is discontinuous.

13. The magnetic recording device according to claim 6, wherein said planar portion has a maximum width of 10 nm or less.

14. The magnetic recording device according to claim 6, further comprising a write bit line and a write word line wired above and below said ferromagnetic region layers, respectively, wherein axes of symmetry of said ferromagnetic region layers are positioned such that the composite magnetic field induced by electric currents applied to said lines functions as said external parallel magnetic field.

15. The magnetic recording device according to claim 14, wherein a plurality of ferromagnetic region layers are vertically positioned with nonmagnetic layers interpositioned between the ferromagnetic region layers such that the planar portions of the ferromagnetic region layers are parallel to one another, and wherein axes of symmetry of the planar portions are vertically positioned at a particular phase difference so that a magnetization direction of any one or more of intermediate ferromagnetic region layers other than the lowermost and/or the uppermost ferromagnetic region layers can be independently controlled by the direction of the composite magnetic field induced from the write bit line and the write word line.

16. A magnetic random access memory comprising a plurality of magnetic recording devices of claim 14 positioned on a non-ferromagnetic substrate such that each magnetic recording device can be selected independently.

17. The magnetic random access memory according to claim 16, wherein said plurality of magnetic recording devices positioned on said non-ferromagnetic substrate are positioned such that the axes of symmetry of the planar portions of the ferromagnetic region layers of a same height in adjacent magnetic recording devices are not in a same direction.

18. A method for producing a mesoscopic magnetic body having a circular single domain structure comprising at least the steps of:
placing a mesoscopic magnetic body which is a tabular ferromagnetic body whose planar portion has an axis of symmetry and is not symmetric in the direction perpendicular to the axis of symmetry, in a region within which an external parallel magnetic field can be applied, such that the axis of symmetry is perpendicular to the direction of the applied magnetic field, and
placing an external magnetic field generating means which is capable of applying the external parallel magnetic field to the mesoscopic magnetic body.

19. The method for producing a mesoscopic magnetic body having a circular single domain structure according to claim 18, wherein said external magnetic field generating means is capable of turning the field on/off and reversing the field.

20. The method for producing a mesoscopic magnetic body having a circular single domain structure according to claim 18, wherein the mesoscopic magnetic body has been patterned by any one of sputtering, electron beam evaporation, molecular beam epitaxy, or a combination thereof.

21. A method for producing a magnetic recording device comprising a mesoscopic magnetic body having a circular single domain structure, wherein the method comprises at least the steps of fabricating a write word line, fabricating a magnetoresistive element, and fabricating a write bit line on a nonmagnetic substrate, and wherein said step of providing a magnetoresistive element at least comprises the steps of:
placing a first mesoscopic magnetic body that is a tabular ferromagnetic body whose planar portion has an axis of symmetry and is not symmetric in the direction perpendicular to the axis of symmetry such that said axis of symmetry is perpendicular to the direction of the composite magnetic field induced by electric currents applied to said write word line and said write bit line;
depositing a nonmagnetic layer on said tabular ferromagnetic body to cover the upper surface of said ferromagnetic body; and
placing a second mesoscopic magnetic body that has the same material as said first mesoscopic magnetic body but a different aspect ratio, vertically above said first mesoscopic magnetic body on the nonmagnetic layer, such that boundaries between the layers are parallel to each other; and
wherein control of the induced composite magnetic field enables control of the magnetization direction of at least said mesoscopic magnetic body having a smaller aspect ratio, upon removal of the induced magnetic field.

22. The method for producing a magnetic recording device according to claim 21, wherein the differential aspect ratio is due to a difference in thickness of the ferromagnetic region layers having an identical planar shape.

23. The method for producing a magnetic recording device according to claim 21, wherein the differential aspect ratio is due to a difference in planar area of the ferromagnetic region layers.

24. The method for producing a magnetic recording device according to claim 18, wherein said planar portion has a shape formed by providing a notch to the outer periphery of a shape having two axes of symmetry perpendicular to each other such that the notch is symmetric to one of the axes but not to the other axis, and
wherein upon application of the external parallel magnetic field, a magnetization direction in the ferromagnetic region layer's periphery shows a circumferential distribution, which includes a part where change of the magnetization direction is discontinuous.

25. The method for producing a magnetic recording device according to claim 18, wherein said planar portion has a shape corresponding to the contour of a projected image of a shape having two axes of symmetry perpendicular to each other over a rectangle that has one of the axes of symmetry as length and a length shorter than half of the other axis of symmetry as width, and
wherein upon application of the external parallel magnetic field, a magnetization direction in the magnetic material's periphery shows a circumferential distribution, which includes a part where change of the magnetization direction is discontinuous.

26. The method for producing a magnetic recording device of claim 18, wherein said planar portion has a maximum width of 10 nm or less.

27. The method for producing a magnetic recording device according to claim 18, wherein a write bit line and a write word line are further provided above and below said ferromagnetic region layers, respectively, wherein axes of symmetry of said ferromagnetic region layers are positioned such that the composite magnetic field induced by electric current applied to said lines functions as said external parallel magnetic field.

28. The method for producing a magnetic recording device according to claim 27, wherein a plurality of ferromagnetic region layers are vertically positioned on one another with nonmagnetic layers interpositioned between the ferromagnetic region layers such that the planar portions of the ferromagnetic region layers are parallel to one another, and wherein axes of symmetry of the planar portions are vertically positioned at a particular phase difference so that magnetization direction of any one or more of intermediate ferromagnetic region layers other than the lowermost and/or the uppermost ferromagnetic region layers can be independently controlled by the direction of the composite magnetic field induced from the write bit line and the write word line.

29. A method for producing a magnetic random access memory comprising the step of placing a plurality of magnetic recording devices on a non-ferromagnetic substrate using the method for producing a magnetic recording device of claim 27, such that each magnetic recording device can be selected independently.

30. The method for producing a magnetic random access memory according to claim 29, wherein said plurality of magnetic recording devices positioned on said non-ferromagnetic substrate are positioned such that the axes of symmetry of the planar portions of the ferromagnetic region layers of a same height in adjacent magnetic recording devices are not in a same direction.

31. The mesoscopic magnetic body according to claim 2,
wherein said planar portion has a shape formed by providing a notch to the outer periphery of a shape that has two axes of symmetry perpendicular to each other, such that the notch is symmetric to one of the axes but not to the other axis, and
wherein upon application of the external parallel magnetic field, a magnetic flux direction in the periphery of the magnetic material shows a circumferential distribution which includes a part where change of the magnetic flux direction is discontinuous.

32. The mesoscopic magnetic body according to claim 2, wherein said planar portion has a shape corresponding to the contour of a projected image of a shape having two axes of symmetry perpendicular to each other over a rectangle that has one of the axes of symmetry as length and a length shorter than half of the other axis of symmetry as width, and
wherein upon application of the external parallel magnetic field, magnetization direction in the magnetic material's periphery shows a circumferential distribution, which includes a part where change of the magnetization direction is discontinuous.

33. The mesoscopic magnetic body according to claim 2 wherein said planar portion has a maximum width of 10 nm or less.

34. The magnetic recording device according to claim 7, wherein said ferromagnetic region layers sandwich a nonmagnetic layer to form a laminate in a vertical direction, and wherein either the upper or the lower ferromagnetic region layer is formed to have an aspect ratio larger than that of the other ferromagnetic region layers such that the magnetization directions of the ferromagnetic region layers with smaller aspect ratios can be controlled independently from the magnetization direction of the ferromagnetic region layer with a larger aspect ratio, and wherein the magnetization directions of the ferromagnetic region layers are detected based on resistance values between the ferromagnetic region layers.

35. The magnetic recording device according to claim 34, wherein the differential aspect ratio is due to a difference in thickness of the ferromagnetic region layers having an identical planar shape.

36. The magnetic recording device according to claim 34, wherein the differential aspect ratio is due to a difference in planar area of the ferromagnetic region layers.

37. The magnetic recording device according to claim 7, wherein said planar portion has a shape formed by providing a notch to the outer periphery of a shape having two axes of symmetry perpendicular to each other, such that the notch is symmetric to one of the axes but not to the other axis, and
wherein upon application of the external parallel magnetic field, magnetization direction in the ferromagnetic region layer's periphery shows a circumferential distribution, which includes a part where change of the magnetization direction is discontinuous.

38. The magnetic recording device according to claim 7, wherein said planar portion has a shape corresponding to the contour of a projected image of a shape having two axes of symmetry perpendicular to each other over a rectangle that has one of the axes of symmetry as length and a length shorter than half of the other axis of symmetry as width, and
wherein upon application of the external parallel magnetic field, magnetization direction in the magnetic material's periphery shows a circumferential distribution, which includes a part where change of the magnetization direction is discontinuous.

39. The magnetic recording device according to claim 7, wherein said planar portion has a maximum width of 10 nm or less.

40. The magnetic recording device according to claim 7, further comprising a write bit line and a write word line wired above and below said ferromagnetic region layers, respectively, wherein axes of symmetry of said ferromagnetic region layers are positioned such that the composite magnetic field induced by electric currents applied to said lines functions as said external parallel magnetic field.

41. The magnetic recording device according to claim 40, wherein a plurality of ferromagnetic region layers are vertically positioned with nonmagnetic layers interpositioned between the ferromagnetic region layers such that the planar portions of the ferromagnetic region layers are parallel to one another, and wherein axes of symmetry of the planar portions are vertically positioned at a particular phase difference so that a magnetization direction of any one or more of intermediate ferromagnetic region layers other than the lowermost and/or the uppermost ferromagnetic region layers can be independently controlled by the direction of the composite magnetic field induced from the write bit line and the write word line.

42. A magnetic random access memory comprising a plurality of magnetic recording devices of claim 40 positioned on a non-ferromagnetic substrate such that each magnetic recording device can be selected independently.

43. The magnetic random access memory according to claim 42, wherein said plurality of magnetic recording devices positioned on said non-ferromagnetic substrate are positioned such that the axes of symmetry of the planar portions of the ferromagnetic region layers of a same height in adjacent magnetic recording devices are not in a same direction.

44. The method for producing a magnetic recording device according to claim 21, wherein said planar portion has a shape formed by providing a notch to the outer periphery of a shape having two axes of symmetry perpendicular to each other such that the notch is symmetric to one of the axes but not to the other axis, and
wherein upon application of the external parallel magnetic field, a magnetization direction in the ferromagnetic region layer's periphery shows a circumferential distribution, which includes a part where change of the magnetization direction is discontinuous.

45. The method for producing a magnetic recording device according to claim 21, wherein said planar portion has a shape corresponding to the contour of a projected image of a shape having two axes of symmetry perpendicular to each other over a rectangle that has one of the axes of symmetry as length and a length shorter than half of the other axis of symmetry as width, and
wherein upon application of the external parallel magnetic field, a magnetization direction in the magnetic material's periphery shows a circumferential distribution, which includes a part where change of the magnetization direction is discontinuous.

46. The method for producing a magnetic recording device of any one of claim 21, wherein said planar portion has a maximum width of 10 nm or less.

47. The method for producing a magnetic recording device according to claim 21, wherein a write bit line and a write word line are further provided above and below said ferromagnetic region layers, respectively, wherein axes of symmetry of said ferromagnetic region layers are positioned such that the composite magnetic field induced by electric current applied to said lines functions as said external parallel magnetic field.

48. The method for producing a magnetic recording device according to claim 47, wherein a plurality of ferromagnetic region layers are vertically positioned on one another with nonmagnetic layers interpositioned between the ferromagnetic region layers such that the planar portions of the ferromagnetic region layers are parallel to one another, and wherein axes of symmetry of the planar portions are vertically positioned at a particular phase difference so that magnetization direction of any one or more of intermediate ferromagnetic region layers other than the lowermost and/or the uppermost ferromagnetic region layers can be independently controlled by the direction of the composite magnetic field induced from the write bit line and the write word line.

49. A method for producing a magnetic random access memory comprising the step of placing a plurality of magnetic recording devices on a non-ferromagnetic substrate using the method for producing a magnetic recording device of claim 47, such that each magnetic recording device can be selected independently.

50. The method for producing a magnetic random access memory according to claim 49, wherein said plurality of magnetic recording devices positioned on said non-ferromagnetic substrate are positioned such that the axes of symmetry of the planar portions of the ferromagnetic region layers of a same height in adjacent magnetic recording devices are not in a same direction.
